(19) United States
(12) Patent Application Publication
(10) Pub. No.: US 2004/0261693 A1
(43) Pub. Date: Dec. 30, 2004

(54) Epitaxial structure and process of GaN based compound semiconductor

(76) Inventors: Mu Jen Lai, Hsin Chu (TW); Chiung Yu Chang, Hsin Chu (TW); Chia Cheng Liu, Hsin Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/603,864

(22) Filed: Jun. 26, 2003

(51) Int. Cl. C30B 25/00; C30B 23/00; C30B 28/12; C30B 28/14

(52) U.S. Cl. 117/86

(57) ABSTRACT

An epitaxial structure of GaN based compound semiconductor comprises a substrate; a single crystal of boron phosphide buffer layer on the substrate; a first buffer layer composed of group III nitride at a temperature from 200 to 800 degree C. formed on the boron phosphide buffer layer; and a second buffer layer composed of group III nitride at a temperature from 800 degree formed on the first buffer layer.

### BACKGROUND OF THE INVENTION

1. Field of the Invention

The present invention relates to a process and epitaxial structure of semiconductor, more particularly, and to a process and epitaxial structure of GaN based compound semiconductor which disclose a buffer layer of group III nitride formed on a single crystal of boron phosphide by growing a first layer at a low temperature and a second layer at a high temperature for growing a lattice-matched structure.

2. Description of the Related Art

The GaN-based compound semiconductor is used to make a LED, LD, high frequency/high efficiency transistor and photodetector, and the LED can emit a light of blue, green, purple and white. The LED broadly applies in lighting equipment because the LED has many functions such as saving energy, long life and safety.

Presently, the LED is composed of group III nitride using a blue sapphire to be a substrate and firstly growing a buffer layer on the substrate for reducing the lattice mismatch between the substrate and group III nitride. The level of the lattice-matched between epitaxial layers would effect the brightness and life time of GaN-based semiconductor, so the technology of firstly growing the buffer layer on the substrate continues to develop such as U.S. Pat. No. 6,475,882 B1. But, the level of the lattice-matched is not perfect enough resulting in the badly performance of GaN-based semiconductor.

The conventional epitaxial growth of GaN-based is used to a silicon substrate which has low cost, but the silicon substrate has a lattice-matched badly. U.S. Pat. No. 6,069,021 discloses using boron phosphide buffer layer to reduce the epitaxial layer of GaN-based of lattice-matched by forming on the silicon substrate. In fact, the lattice constant of above mention of epitaxial GaN-based is 4.51 Å, and the lattice constant of boron phosphide buffer layer is 4.538 Å. The lattice-matched is not only difference but also generating line defect when the epitaxial GaN-based layer forms on the above mentions of both boron phosphide buffer layers at a high temperature.

The present invention discloses a first buffer layer composed of group III nitride formed on a single crystal buffer layer composed of boron phosohide at a low temperature, and a second buffer layer composed of group III nitride formed on the first buffer layer at a high temperature for generating prefect lattice-matched.

### SUMMARY OF THE INVENTION

It is an object of the present invention to provide a process and epitaxial structure of GaN-based compound semiconductor which discloses a process growing a buffer layer composed of GaN-based at a low and high temperature during one process for an epitaxial layer having a perfect lattice-matched with the substrate.

It is another object of the present invention to provide a process and epitaxial structure of GaN-based compound semiconductor which enhance the emitting efficiency, brightness and life time of semiconductors.

It is yet another object of the present invention to provide a process and epitaxial structure of GaN-based compound semiconductor which use a silicon or silicon carbon substrate to replace the conventional blue sapphire for cost down.

For achievement the above mentions, the present invention discloses a buffer layer composed of boron phosphide formed on a substrate and a first buffer layer composed of group III nitride formed on the boron phosphide buffer layer at a low temperature. Furthermore, a second buffer layer composes of group III nitride forms on the first buffer layer at a high temperature.

The substrate comprises single crystal silicon. The boron phosphide is single crystal comprises a first layer formed at a temperature form 300 degree C. to 850 degree C. and a second layer formed at a temperature form 800 degree C. and 1100 degree C. And, the first buffer layer is formed at a temperature from 200 degree C. to 800 degree C., and the second buffer layer is formed at a temperature from 800 degree C. to 1100 degree C.

The first and second buffer layers are made of AlₓIn_{y}Ga_{z}N, wherein 0≦x ≦1, 0≦y≦1, 0≦z≦1, x+y+z=1 or InₓGa_{y}N_{z}P, wherein 0≦x≦1, 0≦y≦1, 0≦z≦1, x+y+z=1.

It is to be understood that both the foregoing general description and the following detailed description are exemplary, and are intended to provide further explanation of the invention as claimed.

### BRIEF DESCRIPTION OF DRAWINGS

The accompanying drawing is included to provide a further understanding of the invention, and is incorporated in and constitutes a part of this specification. The drawing illustrates an embodiment of the invention and, together with the description, serves to explain the principles of the invention. In the drawing,

FIGS. 1 to 5 are an illustrated view showing the structure of GaN-based semiconductor in accordance to an embodiment of the present invention.

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

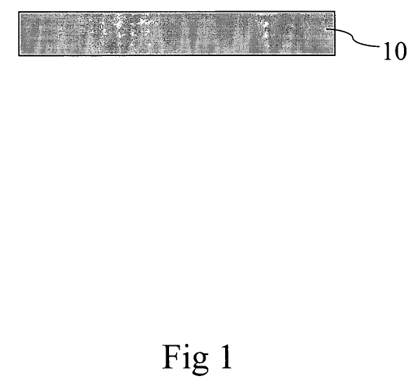

Referring to FIGS. 1 to 5, the present invention discloses an epitaxial structure of GaN-based compound semiconductor comprising a first layer 12 composed of boron phosphide formed at a low temperature, a second layer 14 composed of boron phosphide formed at a high temperature, a first buffer layer 16 composed of group III nitride and a second buffer layer 18 composed of group III nitride orderly formed on the substrate 10.

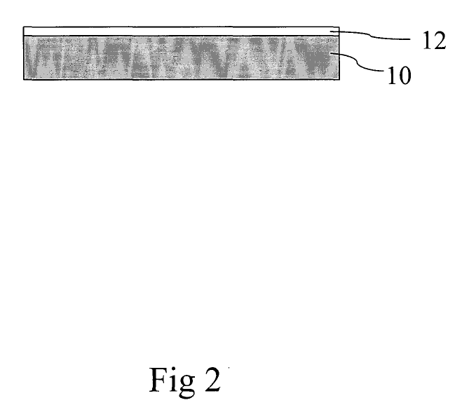

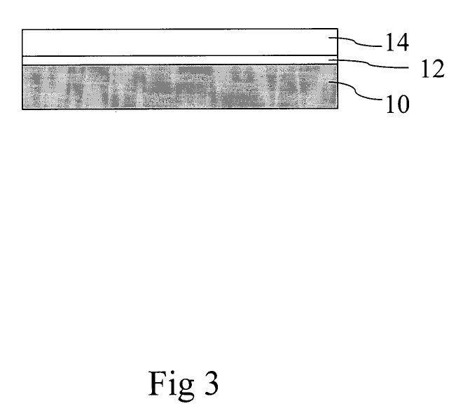

Firstly, seeing FIG. 1, a substrate 10 is single crystal silicon or silicon carbon and cleaned by a chemical solution by conventional chemical liquid within the environment of hydrogen, and heating the substrate 10 at a about temperature of 900 degree C. then, referring to FIGS. 2 and 3, a polycrystalline structure of first layer 12 is grown on the substrate 10 by a halide vapor phase epitaxy method and the second layer 14 which is a single crystal structure is formed on the first layer 12 at a high temperature so that the first layer 12 should transform form the polycrystalline structure to single crystal one.

The halide vapor phase epitaxy method is to use a hydrogen gas to be a carrier gas and BCl₃, PCl₃ or BCl₃, PH₃ to be a precursor for driving the process. The growth of first layer composed of boron phosphide is formed about 400 nm thickness at a temperature from 300 degree C. to 850 degree C. And, the growth of second layer composed of boron phosphide is formed about 4560 nm thickness at a temperature from 800 degree C. to 1100 degree C., and the prefered temperature is 1030 degree C.

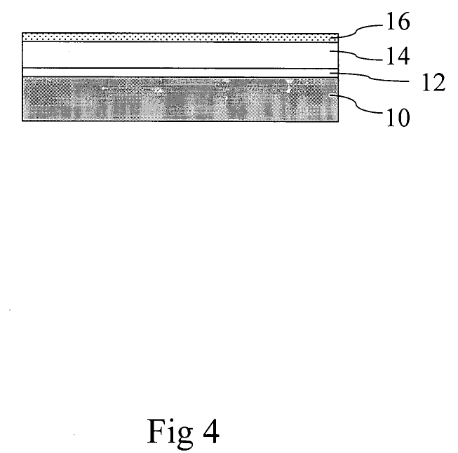

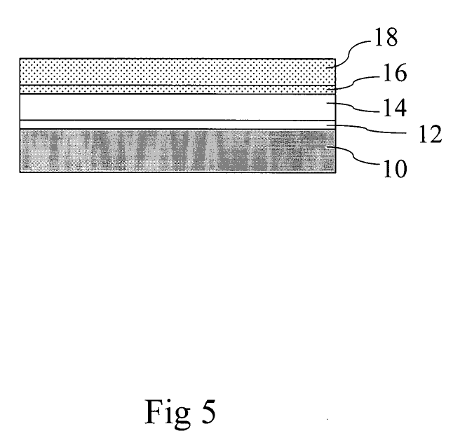

Referring to FIGS. 4 and 5, the present invention discloses a first buffer layer 16 and a second buffer layer 18 orderly formed on the second layer 14 by the metal-organ chemical vapor deposition method, and the first buffer layer 16 is formed at a low epitaxial temperature from 200 degree C. to 800 degree C., and the preferred temperature is from 450 degree C. to 600 degree C. Further, the second buffer layer 18 formed on the first buffer layer 16 is formed at a high epitaxial temperature from 800 degree C. to 1100 degree C., and the better temperature is 800 degree C. And, the first and second buffer layers 16, 18 are composed of group III nitride such as AlₓIn_{y}Ga_{z}N, wherein 0≦x≦1, 0≦y≦1, 0≦z≦1, x+y+z=1 or InₓGa_{y}N_{z}P, wherein 0≦x≦1, 0≦y≦1, 0≦z≦1, x+y+z=1.

For the precursors of first and second layers 16,18, monomethyl hydrazine, trimethyl gallium, trimethyl aluminum, trimethyl indium and NH₃ are usually selected in metal-organ chemical vapor deposition process.

The present invention discloses a substrate composed of silicon (lattice constant=5.431 Å) and having diamond structure. The boron phosphide(lattice constant=4.538 Å) has a zinc blende structure and lattice structure as same as the diamond. So, the lattice of silicon substrate and boron phosphide is not matched reaching to about 16% which is lower than the conventional one resulting in the excellent lattice structure of epitaxial layer.

The present invention discloses a boron phosphide buffer layer formed on the substrate for getting the better lattice-matched and using in similar process orderly growing two GaN-based buffer layers at a low and high temperature for getting the better lattice-matched between boron phosphide and GaN-based buffer layer. So, the present invention is different from the conventional sapphire that the present invention has a low cost for getting excellent lattice-matched to enhance the emitting efficiency, brightness and time life of the semiconductors.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed is:

1. An epitaxial structure of GaN based compound semiconductor comprising:
a substrate;
a single crystal of boron phosphide buffer layer on said substrate;
a first buffer layer composed of group III nitride at a temperature from 200 to 800 degree C. formed on said boron phosphide buffer layer; and
a second buffer layer composed of group III nitride at a temperature from 800 to 1100 degree C. formed on said first buffer layer.

2. The epitaxial structure of GaN based compound semiconductor of claim 1, wherein said substrate is a single crystal silicon.

3. The epitaxial structure of GaN based compound semiconductor of claim 1, wherein said boron phosphide buffer layer comprises a first layer formed at a temperature from 300 to 850 degree C. and a second layer formed at a temperature from 800 to 1100 degree C.

4. The epitaxial structure of GaN based compound semiconductor of claim 1, wherein said first and second buffer layer are composed of AlₓIn_{y}Ga_{z}N, wherein 0≦x≦1, 0≦y≦1, 0≦z≦1, x+y+z=1.

5. The epitaxial structure of GaN based compound semiconductor of claim 1, wherein said first and second buffer layer are composed of InₓGa_{y}N_{z}P, wherein 0≦x≦1, 0≦y≦1, 0≦z≦1, x+y+z=1.

6. A process of epitaxial structure of GaN based compound semiconductor, comprising the steps of:
providing a substrate;
growing a single crystal of boron phosphide buffer layer on said substrate;
growing a first buffer layer composed of group III nitride formed on said boron phosphide buffer layer at a temperature from 200 to 800 degree C.;
and growing a second buffer layer composed of group III nitride formed on said first buffer layer at a temperature from 800 to 1100 degree C.

7. The process of epitaxial structure of GaN based compound semiconductor of claim 6, wherein said substrate is a single crystal silicon.

8. The process of epitaxial structure of GaN based compound semiconductor of claim 6, wherein said boron phosphide buffer layer comprises a first layer formed at a temperature from 300 to 850 degree C. and a second layer formed at a temperature from 800 to 1100 degree C.

9. The process of epitaxial structure of GaN based compound semiconductor of claim 6, wherein said first and second buffer layer are composed of AlₓIn_{y}Ga_{z}N, wherein wherein 0≦x≦1, 0≦y≦1, 0≦z≦1, x+y+z=1.

10. The process of epitaxial structure of GaN based compound semiconductor of claim 6, wherein said first and second buffer layer are composed of InₓGa_{y}N_{z}P, wherein 0≦x≦1, 0≦y≦1, 0≦z≦1, x+y+z=1.
